(19) United States
(12) Patent Application Publication
(10) Pub. No.: US 2023/0290793 A1
(43) Pub. Date: Sep. 14, 2023

(54) IMAGING DEVICE

(71) Applicant: Panasonic Intellectual Property Management Co., Ltd., Osaka (JP)

(72) Inventors: MORIKAZU TSUNO, Shiga (JP); JUNJI HIRASE, Osaka (JP)

(21) Appl. No.: 18/317,384

(22) Filed: May 15, 2023

Related U.S. Application Data
(63) Continuation of application No. PCT/JP2021/041253, filed on Nov. 9, 2021.

(30) Foreign Application Priority Data
Dec. 2, 2020 (JP) 2020-200065

(51) Int. Cl. H01L 27/146

(52) U.S. Cl. CPC H01L 27/14612; H01L 27/1463

(57) ABSTRACT

An imaging device includes: a photoelectric converter that generates a signal charge by photoelectric conversion; a semiconductor substrate that includes a first semiconductor layer containing an impurity of a first conductivity type; a charge accumulation region that is an impurity region of a second conductivity type in the first semiconductor layer and that accumulates the signal charge; a transistor that includes, as one of a source and a drain, a first impurity region of the second conductivity type in the first semiconductor layer; and a blocking structure located between the charge accumulation region and the first impurity region. The blocking structure includes a second impurity region of the first conductivity type in the first semiconductor layer and a third impurity region of the first conductivity type in the first semiconductor layer, the third impurity region having an impurity concentration different from that of the second impurity region.

### BACKGROUND

### 1. Technical Field

The present disclosure relates to an imaging device.

### 2. Description of the Related Art

Charge-coupled device (CCD) image sensors and complementary metal-oxide semiconductor (CMOS) image sensors are widely used for digital cameras and the like. These image sensors have a photodiode formed on a semiconductor substrate.

For example, as disclosed in International Publication No. WO 2012/147302, there is also proposed a structure in which a photoelectric conversion layer is disposed above the semiconductor substrate in place of the photodiode. An imaging device having such a structure is sometimes called a stack-type imaging device. In a stack-type imaging device, as signal charges, charges generated by photoelectric conversion are temporarily accumulated in, e.g., a diffusion region formed at the semiconductor substrate. A signal according to the amount of charges accumulated is read via a CCD circuit or a CMOS circuit formed at the semiconductor substrate.

### SUMMARY

In one general aspect, the techniques disclosed here feature an imaging device including: a photoelectric converter that generates a signal charge by photoelectric conversion; a semiconductor substrate that includes a first semiconductor layer containing an impurity of a first conductivity type; a charge accumulation region that is an impurity region of a second conductivity type in the first semiconductor layer and that accumulates the signal charge; a transistor that includes, as one of a source and a drain, a first impurity region of the second conductivity type in the first semiconductor layer; and a blocking structure located between the charge accumulation region and the first impurity region. The blocking structure includes a second impurity region of the first conductivity type in the first semiconductor layer and a third impurity region of the first conductivity type in the first semiconductor layer, the third impurity region having an impurity concentration different from an impurity concentration of the second impurity region.

Comprehensive or specific aspects may be implemented as an element, a device, a module, a system, or method. Comprehensive or specific aspects may be also implemented as any selective combination of the element, the device, an apparatus, the module, the system.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

The present disclosure can reduce dark current.

### BRIEF DESCRIPTION OF THE DRAWINGS

FIG. 1 is a diagram showing an example configuration of an imaging device according to Embodiment 1 of the present disclosure;

FIG. 2 is a schematic diagram showing an example circuit configuration of the imaging device according to Embodiment 1 of the present disclosure;

FIG. 3 is a sectional view schematically showing an example of the device structure of a pixel in the imaging device according to Embodiment 1 of the present disclosure;

FIG. 4 is a schematic plan view showing an example layout of elements in a pixel in the imaging device according to Embodiment 1 of the present disclosure;

FIG. 5A is a diagram showing potentials at a blocking structure in a pixel in an imaging device according to a comparative example;

FIG. 5B is a diagram showing potentials at a blocking structure in a pixel in the imaging device according to Embodiment 1 of the present disclosure;

FIG. 6 is a diagram showing how dark current in a pixel in the imaging device according to Embodiment 1 of the present disclosure is dependent on the impurity concentration of the blocking structure;

FIG. 7 is a sectional view schematically showing an example of the device structure of a pixel in an imaging device according to Embodiment 2 of the present disclosure;

FIG. 8 is a schematic plan view showing an example layout of elements in a pixel in the imaging device according to Embodiment 2 of the present disclosure; and

FIG. 9 is a sectional view schematically showing an example of the device structure of a pixel in an imaging device according to a modification of the embodiments of the present disclosure.

### DETAILED DESCRIPTIONS

Charges different from signal charges representing an image may cause noise when flowing into a diffusion region that temporarily holds the signal charges, and the noise degrades a resultant image. It is beneficial if such unintended charge movement can be reduced. In the following, such unintended charge movement may be expressed as dark current or leak current.

The present disclosure provides an imaging device that can reduce dark current.

### Overview of the Present Disclosure

An overview of aspects of the present disclosure are as follows.

An imaging device according to an aspect of the present disclosure includes: a photoelectric converter that generates a signal charge by photoelectric conversion; a semiconductor substrate that includes a first semiconductor layer containing an impurity of a first conductivity type; a charge accumulation region that is an impurity region of a second conductivity type in the first semiconductor layer and that accumulates the signal charge; a transistor that includes, as one of a source and a drain, a first impurity region of the second conductivity type in the first semiconductor layer; and a blocking structure located between the charge accumulation region and the first impurity region. The blocking structure includes a second impurity region of the first conductivity type in the first semiconductor layer and a third impurity region of the first conductivity type in the first semiconductor layer, the third impurity region having an impurity concentration different from that of the second impurity region. On a line connecting the charge accumulation region and the first impurity region, the charge accumulation region, the second impurity region, the third impurity region, and the first impurity region are disposed in this order.

When the blocking structure thus includes a region with a high concentration of an impurity of the first conductivity type between the first impurity region of the second conductivity type and the charge accumulation region, recombination of minority carriers generated at the p-n junction of the first impurity region of the second conductivity type can be accelerated, which helps prevent minority carriers from flowing into the charge accumulation region. Thus, the provision of the blocking structure enables reduction in dark current flowing to the charge accumulation region.

Meanwhile, minority carriers not recombined in the blocking structure of the first conductivity type have the property of being diffused in the direction of a lower impurity concentration. For this reason, the minority carriers may flow not only into the first impurity region but also into the charge accumulation region.

According to the imaging device according to the aspect of the present disclosure, in a plan view, a distance between the second impurity region and the charge accumulation region may be shorter than a distance between the third impurity region and the charge accumulation region. For example, the second impurity region may have a higher impurity concentration than the third impurity region.

Thus, the second impurity region functions as a diffusion barrier against minority carriers generated at the p-n junction of the first impurity region. This helps prevent minority carriers from flowing into the charge accumulation region. Consequently, image degradation due to dark current generated in the charge accumulation region can be reduced even more.

For example, the second impurity region may be in direct contact with the third impurity region.

An imaging device according to another aspect of the present disclosure includes: a photoelectric converter that generates a signal charge by photoelectric conversion; a semiconductor substrate that includes a first semiconductor layer containing an impurity of a first conductivity type; a charge accumulation region that is an impurity region of a second conductivity type in the first semiconductor layer and that accumulates the signal charge; a transistor that includes, as one of a source and a drain, a first impurity region of the second conductivity type in the first semiconductor layer; and a blocking structure located between the charge accumulation region and the first impurity region. The blocking structure includes a second impurity region of the first conductivity type in the first semiconductor layer and a third impurity region of the first conductivity type in the first semiconductor layer, the third impurity region having an impurity concentration different from an impurity concentration of the second impurity region. The first semiconductor layer may include a second semiconductor layer containing an impurity of the first conductivity type and a third semiconductor layer being adjacent to the second semiconductor layer in a plan view and having an impurity concentration different from an impurity concentration of the second semiconductor layer. The charge accumulation region may be included in the third semiconductor layer. The first impurity region may be included in the second semiconductor layer. In the plan view, the second impurity region may overlap with a border between the second semiconductor layer and the third semiconductor layer.

This allows the region surrounding the charge accumulation region to have a lower impurity concentration and thus can reduce the p-n junction leakage in the charge accumulation region.

For example, the semiconductor substrate may further include a fourth semiconductor layer containing an impurity of the second conductivity type, and the first semiconductor layer may be located between the photoelectric converter and the fourth semiconductor layer.

Thus, minority carriers generated at the p-n junction of the first impurity region are likely to be released to the fourth semiconductor layer through the third semiconductor layer with a low impurity concentration. This helps prevent minority carriers from flowing into the charge accumulation region, and dark current can be reduced even more.

For example, the third semiconductor layer may have a lower impurity concentration than the second semiconductor layer.

When the third semiconductor layer thus has a lower impurity concentration, p-n junction leakage in the charge accumulation region inside the third semiconductor layer can be reduced. Consequently, dark current can be reduced even more.

For example, at least part of the second impurity region, at least part of the third impurity region, or both of the at least part of the second impurity region and the at least part of the third impurity region may be located at a surface of the semiconductor substrate.

For example, the transistor may include a first gate electrically connected to the photoelectric converter.

For example, in a plan view, the second impurity region may surround the charge accumulation region.

For example, in a plan view, the third impurity region may surround the transistor.

For example, in a plan view, the second impurity region may not overlap with the third impurity region.

An imaging device according to still another aspect of the present disclosure includes: a photoelectric converter that generates a signal charge by photoelectric conversion; a semiconductor substrate that includes a first semiconductor layer containing an impurity of a first conductivity type; a charge accumulation region that is an impurity region of a second conductivity type in the first semiconductor layer and that accumulates the signal charge; a transistor that includes, as one of a source and a drain, a first impurity region of the second conductivity type in the first semiconductor layer; and a blocking structure located between the charge accumulation region and the first impurity region. The blocking structure includes a second impurity region of the first conductivity type in the first semiconductor layer and a third impurity region of the first conductivity type in the first semiconductor layer, the third impurity region having an impurity concentration different from an impurity concentration of the second impurity region. The second impurity region is in direct contact with the third impurity region, and in a plan view, the second impurity region does not overlap with the third impurity region.

For example, in the plan view, a distance between the second impurity region and the charge accumulation region may be shorter than a distance between the third impurity region and the charge accumulation region, and the second impurity region may have a higher impurity concentration than the third impurity region.

In the present disclosure, all or some of the circuits, units, apparatuses, members, or portions or all or some of the functional blocks of the block diagram may be executed by one or more electric circuits including a semiconductor apparatus, a semiconductor integrated circuit (IC), or a large scale integration (LSI). The LSI or the IC may be integrated in one chip or may be formed by a combination of a plurality of chips. For example, the functional blocks except for a storage element may be integrated in one chip. Although electric circuits called LSI or IC are used herein, the electric circuits are called differently depending on the degree of integration, and ones called system LSI, very large scale integration (VLSI), or ultra large scale integration (ULSI) may be used. A field-programmable gate array (FPGA) programmed after manufacturing of an LSI or a reconfigurable logic device capable of reconfiguring the connections between the internal constituents of the LSI or setting up circuit sections inside the LSI can also be used for the same purpose.

Further, the functions or operations of all or some of the circuits, units, apparatuses, members, or portions may be executed by software processing. In this case, the software is recorded in one or more non-temporary recording media such as a ROM, an optical disk, and a hard disk drive, and when the software is executed by a processor, a function identified by the software is executed by the processor and a peripheral device. The system or apparatus may include one or more non-temporary recording media in which software is recorded, the processor, and necessary hardware devices such as, for example, an interface.

Embodiments of the present disclosure are described in detail below with reference to the drawings. Note that the embodiments described below each show a comprehensive or specific example. Numeric values, shapes, materials, constituents, the arrangement and connection of the constituents, steps, the order of the steps, and the like shown in the following embodiments are examples and are not intended to limit the present disclosure. Various aspects described herein can be combined as long as no contradiction arises. Also, of constituents in the following embodiments, ones not described in independent claims are described as optional constituents. The following description may use the same reference numeral for constituents having substantially the same function and omit descriptions. Also, in order for the drawings not to be overly complicated, some elements may be omitted in the drawings.

Also, various elements shown in the drawings are shown schematically only for the understanding of the present disclosure, and may have actual dimensional ratios and outer appearances different from actual ones. In other words, the drawings are schematic diagrams and are not necessarily depicted precisely. Thus, for example, the reduction scales are not necessarily the same between the drawings.

Also, herein, terms describing the relation between elements, such as parallel or uniform, terms describing the shape of an element, such as circular or rectangular, and numerical ranges are meant not only to express the exact meanings, but also to include a substantially equivalent range with a difference of, for example, approximately a few percent.

Also, herein, terms “above” and “below” are not used to refer to the upward direction (upward vertically) and the downward direction (downward vertically) in the absolute spatial recognition, but used as terms defined by the relative positional relation based on the stacking order in a stacked configuration. Specifically, the light receiving side of the imaging device is “above,” and the opposite side from the light receiving side is “below.” The same applies to the “upper surface” and the “lower surface” of each member; the surface facing the light receiving side of the imaging device is an “upper surface,” and the surface facing the opposite side from the light receiving side is a “lower surface.” Note that the terms “above,” “below,” “upper surface,” and “lower surface” are used only to specify the placement of members relative to each other and are not intended to limit the posture of the imaging device during use. Also, the terms “above” and “below” are used not only for a state where two constituents are disposed apart from each other with another constituent being present between the constituents, but also for a state where two constituents are disposed closely to each other and in contact with each other. Also, herein, a “plan view” is a view seen in a direction perpendicular to the semiconductor substrate.

### Embodiment 1

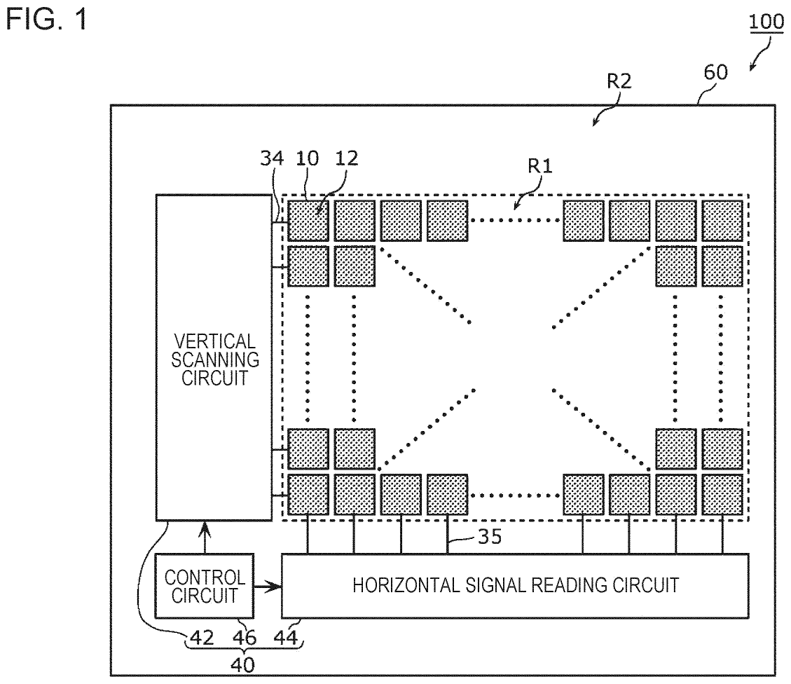

FIG. 1 is a diagram showing an example configuration of an imaging device according to Embodiment 1 of the present disclosure. An imaging device 100 shown in FIG. 1 has a plurality of pixels 10 and peripheral circuits 40 formed on a semiconductor substrate 60.

Each pixel 10 has a photoelectric converter 12. The photoelectric converter 12, upon receipt of light, generates positive and negative charges, or typically, hole-electron pairs. The photoelectric converter 12 may be a photoelectric conversion structure including a photoelectric conversion layer disposed above the semiconductor substrate 60 or may be a photodiode formed at the semiconductor substrate 60. Although FIG. 1 depicts the photoelectric converters 12 of the respective pixels 10 as if they are spatially separated from each other, this is only for the convenience of description, and the photoelectric converters 12 of the plurality of pixels 10 may be disposed on the semiconductor substrate 60 successively without any gap therebetween.

In the example shown in FIG. 1, the pixels 10 are arranged in m rows and n columns, m and n independently being an integer of 1 or greater. For example, the pixels 10 are arranged two-dimensionally at the semiconductor substrate 60 to form an image capture region R1. When the pixels 10 each have, for example, a photoelectric converter 12 disposed above the semiconductor substrate 60, the image capture region R1 may be defined as a region of the semiconductor substrate 60 that is covered by the photoelectric converters 12.

The number and arrangement of the pixels 10 are not limited to the example shown in FIG. 1. For example, the imaging device 100 may include one pixel 10. Although the center of each pixel 10 is located on the grid point of a square grid in this example, the plurality of pixels 10 may be disposed so that, for example, the center of each pixel 10 may be located on a grid point of a triangular grid, a hexagonal grid, or the like. For example, the pixels 10 may be arranged one-dimensionally, in which case the imaging device 100 may be used as a line sensor.

In the configuration exemplified in FIG. 1, the peripheral circuits 40 include a vertical scanning circuit 42 and a horizontal signal reading circuit 44. As exemplified in FIG. 1, the peripheral circuits 40 may additionally include a control circuit 46. The peripheral circuits 40 may further include, for example, a voltage supply circuit that supplies a predetermined voltage to the pixels 10 and the like. The peripheral circuits 40 may further include a signal processing circuit, an output circuit, and the like. The peripheral circuits 40 are disposed in a peripheral region R2. The peripheral region R2 is a region surrounding the image capture region R1.

The vertical scanning circuit 42 is also called a row scanning circuit and has connections to address signal lines 34 provided in correspondence to the respective rows of the plurality of pixels 10. As will be described later, signal lines provided in correspondence to the respective rows of the plurality of pixels 10 are not limited to the address signal lines 34, and a plurality of kinds of signal lines may be connected to the vertical scanning circuit 42 for each row of the plurality of pixels 10. The horizontal signal reading circuit 44 is also called a column scanning circuit and has connections to vertical signal lines 35 provided in correspondence to the respective rows of the plurality of pixels 10.

The control circuit 46 performs overall control of the imaging device 100 by receiving command data, clock signals, and the like given from, e.g., the outside of the imaging device 100. Typically, the control circuit 46 has a timing generator and supplies driving signals to the vertical scanning circuit 42, the horizontal signal reading circuit 44, the voltage supply circuit, and the like. In FIG. 1, the arrows extending from the control circuit 46 schematically depict the flow of output signals from the control circuit 46. The control circuit 46 may be implemented by, for example, a microcontroller including one or more processors. The functions of the control circuit 46 may be implemented by a combination of a general-purpose processing circuit and software or by hardware specialized for such processing.

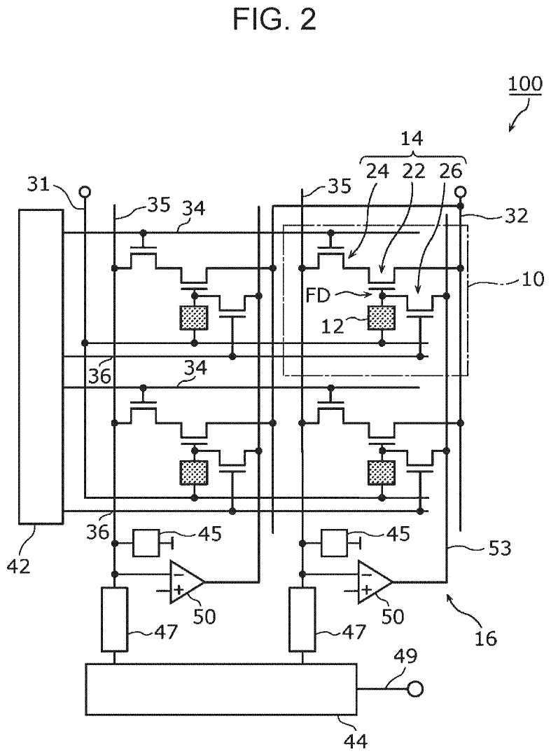

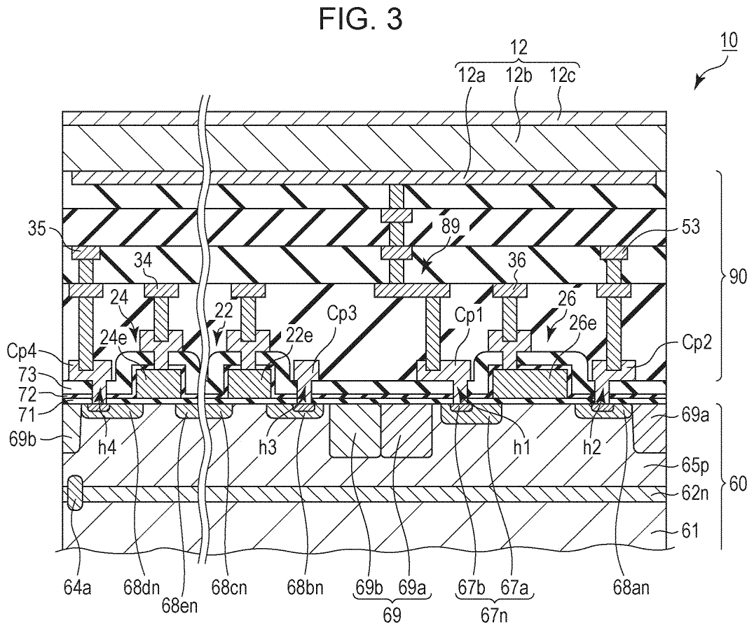

FIG. 2 is a schematic diagram schematically showing an example circuit configuration of the imaging device according to Embodiment 1 of the present disclosure. In order for FIG. 2 not to be complicated, FIG. 2 shows four pixels 10 arranged in two rows and two columns as representatives. Each of these pixels 10 is an example of the pixels 10 shown in FIG. 1. Each pixel 10 has the photoelectric converter 12 and includes a signal detection circuit 14 electrically connected to the photoelectric converter 12. As will be described in detail later with reference to FIG. 3, the photoelectric converter 12 includes a photoelectric conversion layer 12b disposed above the semiconductor substrate 60. Thus, here, a stack-type imaging device is shown as an example of the imaging device 100.

The photoelectric converter 12 of each pixel 10 has a connection to an accumulation control line 31. When the imaging device 100 is in operation, a predetermined voltage is applied to the accumulation control line 31. For example, if positive charges are used as signal charges out of the positive and negative charges generated by photoelectric conversion, positive charges of, for example, approximately 10 V may be applied to the accumulation control line 31 when the imaging device 100 is in operation. An example of using holes as signal changes is shown below.

In the configuration exemplified in FIG. 2, the signal detection circuit 14 includes a signal detection transistor 22, an address transistor 24, and a reset transistor 26. As will be described in detail later with reference to the drawings, the signal detection transistor 22, the address transistor 24, and the reset transistor 26 are typically a field effect transistor (FET) formed at the semiconductor substrate 60 supporting the photoelectric converter 12. An example of using an N-channel MOSFET as a transistor is described below, unless otherwise noted.

As schematically shown in FIG. 2, the gate of the signal detection transistor 22 is electrically connected to the photoelectric converter 12. In the example shown, a charge accumulation node FD at which the gate of the signal detection transistor 22 is connected to the photoelectric converter 12 has a function to temporarily hold the charges generated by the photoelectric converter 12. For example, holes can be stored as signal charges at the charge accumulation node FD by application of a predetermined voltage to the accumulation control line 31 when the imaging device 100 is in operation. As will be described later with reference to the drawings, the charge accumulation node FD includes, as a part thereof, impurity regions formed in the semiconductor substrate 60.

The drain of the signal detection transistor 22 is connected to power source wiring 32 that supplies a power source voltage VDD of, for example, approximately 3.3 V to each pixel 10 when the imaging device 100 is in operation, and the source of the signal detection transistor 22 is connected to a vertical signal line 35 via the address transistor 24. When supplied with the power source voltage VDD to its drain, the signal detection transistor 22 outputs a signal voltage according to the amount of signal charges accumulated in the charge accumulation node FD.

The address signal line 34 is connected to the gate of the address transistor 24 connected between the signal detection transistor 22 and the vertical signal lines 35. The vertical scanning circuit 42 applies a row selection signal for controlling the on and off of the address transistor 24 to the address signal line 34. As a result of this, an output from the signal detection transistor 22 of the selected pixel 10 can be read to the corresponding vertical signal line 35. Note that the placement of the address transistor 24 is not limited to the example shown in FIG. 2 and may be placed between the drain of the signal detection transistor 22 and the power source wiring 32.

A load circuit 45 and a column signal processing circuit 47 are connected to each of the vertical signal lines 35. The load circuit 45 forms a source-follower circuit with the signal detection transistor 22. The column signal processing circuit 47 is also called a row signal accumulation circuit and performs noise reduction signal processing typified by correlated double sampling, analog-to-digital conversion, and the like. The horizontal signal reading circuit 44 sequentially reads signals from the plurality of column signal processing circuits 47 to a horizontal shared signal line 49. The load circuit 45 and the column signal processing circuit 47 may be part of the above-described peripheral circuits 40.

A reset signal line 36 having a connection to the vertical scanning circuit 42 is connected to the gate of the reset transistor 26. The reset signal line 36 is provided for each row of the plurality of pixels 10, like the address signal lines 34. The vertical scanning circuit 42 can select the pixels 10 to be reset on a row basis by applying a row selection signal to the address signal line 34 and can switch the reset transistor 26 of the selected row on and off by applying a reset signal to the gate of the reset transistor 26 via the reset signal line 36. When the reset transistor 26 is turned on, the potential at the charge accumulation node FD is reset.

In this example, one of the drain and source of the reset transistor 26 is connected to the charge accumulation node FD, and the other one of the drain and source of the reset transistor 26 is connected to a corresponding one of feedback lines 53 provided for the respective rows of the plurality of pixels 10. In other words, in this example, a voltage from the feedback line 53 is supplied to the charge accumulation node FD as a reset voltage for resetting charges from the photoelectric converter 12.

In the configuration exemplified in FIG. 2, the imaging device 100 has a feedback circuit 16 including an inverting amplifier 50 as part of a feedback route. As shown in FIG. 2, the inverting amplifier 50 is provided for each row of the plurality of pixels 10, and the above-described feedback line 53 is connected to the output terminal of a corresponding one of the plurality of inverting amplifiers 50. The inverting amplifier 50 may be one of the above-described peripheral circuits 40.

As shown in FIG. 2, the inverting input terminal of the inverting amplifier 50 is connected to the vertical signal line 35 for the corresponding row, and the non-inverting input terminal of the inverting amplifier 50 is supplied with a reference voltage Vref which is a positive voltage of or close to, for example, 1 V when the imaging device 100 is in operation. Turning on the address transistor 24 and the reset transistor 26 forms a feedback route for negatively feeding back an output of that pixel 10, and the formation of the feedback route causes the voltage at the vertical signal line 35 to converge to the input voltage Vref to the non-inverting input terminal of the inverting amplifier 50. In other words, the formation of the feedback route causes the voltage at the charge accumulation node FD to be reset to a voltage that causes the voltage at the vertical signal line 35 to be Vref. A voltage of any level within a range from the power source voltage and the ground may be used as the voltage Vref. The formation of the feedback route can reduce reset noise generated when the reset transistor 26 is turned off. Details of reset noise reduction by using feedback are described in International Publication No. WO 2012/147302. The entire contents disclosed in International Publication No. WO 2012/147302 are incorporated herein by reference.

### (Device Structure of the Pixel 10)

FIG. 3 is a sectional view schematically showing an example device structure of the pixel 10 in the imaging device 100 according to Embodiment 1 of the present disclosure. The pixel 10 roughly includes the semiconductor substrate 60, the photoelectric converter 12 disposed above the semiconductor substrate 60, and a conductive structure 89. As shown in FIG. 3, the photoelectric converter 12 is supported by an interlayer insulating layer 90 covering the semiconductor substrate 60. The conductive structure 89 is disposed inside the interlayer insulating layer 90. In the example shown in FIG. 3, the interlayer insulating layer 90 includes a plurality of insulating layers. The conductive structure 89 includes part of each of a plurality of wiring layers disposed inside the interlayer insulating layer 90. The plurality of wiring layers disposed inside the interlayer insulating layer 90 may include, for example, a wiring layer having, as a part thereof, the address signal line 34, the reset signal line 36, and the like and a wiring layer having, as a part thereof, the vertical signal line 35, the power source wiring 32, the feedback line 53, and the like. It goes without saying that the number of the insulating layers and the number of wiring layers inside the interlayer insulating layer 90 are not limited to this example and can be set to any numbers.

The photoelectric converter 12 includes a pixel electrode 12a formed on the interlayer insulating layer 90, an opposite electrode 12c disposed on the light entry side, and the photoelectric conversion layer 12b disposed between the pixel electrode 12a and the opposite electrode 12c. The photoelectric conversion layer 12b is formed of an organic material or an inorganic material such as amorphous silicon, and performs photoelectric conversion when receiving light via the opposite electrode 12c and thereby generates positive and negative charges. The photoelectric conversion layer 12b is typically formed continuously over a plurality of pixels 10. The photoelectric conversion layer 12b is, in a plan view, formed in the form of a single plate covering a large portion of the image capture region R1 of the semiconductor substrate 60. Thus, the photoelectric conversion layer 12b is shared by a plurality of pixels 10. In other words, the photoelectric converter 12 provided for each pixel 10 includes a part of the photoelectric conversion layer 12b, the part being different for each of the pixels 10. Also, the photoelectric conversion layer 12b may include a layer formed of an organic material and a layer formed of an inorganic material. The photoelectric conversion layer 12b may be provided separately for each pixel 10.

The opposite electrode 12c is a translucent electrode formed of a transparent conductive material such as indium tin oxide (ITO). The term “translucent” used herein means that at least part of the light of a wavelength that the photoelectric conversion layer 12b can absorb is transmitted, and it is not essential that light of the entire wavelength range of visible light be transmitted. Typically, the opposite electrode 12c is, like the photoelectric conversion layer 12b, continuously formed over a plurality of pixels 10. Thus, the opposite electrode 12c is shared by a plurality of pixels 10. In other words, the photoelectric converter 12 provided for each pixel 10 includes a part of the opposite electrode 12c, the part being different for each of the pixels 10. The opposite electrode 12c may be provided separately for each pixel 10.

The opposite electrode 12c has a connection to the above-described accumulation control line 31, although the connection is not shown in FIG. 3. When the imaging device 100 is in operation, by controlling the potential at the accumulation control line 31 to make the potential at the opposite electrode 12c higher than the potential at the pixel electrode 12a, the pixel electrode 12a can selectively select positive charges out of the positive and negative charges generated by photoelectric conversion. When the opposite electrode 12c is formed in the form of a single layer continuously extending over a plurality of pixels 10, a predetermined voltage can be applied to the opposite electrodes 12c of the plurality of pixels 10 at once.

The pixel electrode 12a is an electrode formed of a metal such as aluminum or copper, a metal nitride, or polysilicon made to be conductive by impurity doping. The pixel electrode 12a is electrically separated from the pixel electrodes 12a of the other neighboring pixels 10 by being spatially separated from the pixel electrodes 12a of the other pixels 10.

The conductive structure 89 typically includes a plurality of wiring portions and plugs formed of a metal such as copper or tungsten or of a metal compound such as a metal nitride or a metal oxide and a polysilicon plug. One end of the conductive structure 89 is connected to the pixel electrode 12a. The other end of the conductive structure 89 is connected to a circuit element formed at the semiconductor substrate 60, so that the pixel electrode 12a of the photoelectric converter 12 and the circuit on the semiconductor substrate 60 are electrically connected to each other.

Now, focusing on the semiconductor substrate 60, as schematically shown in FIG. 3, the semiconductor substrate 60 includes a support substrate 61 and one or more semiconductor layers formed on the support substrate 61. As the one or more semiconductor layers, the semiconductor substrate 60 has an n-type semiconductor layer 62n on the support substrate 61 and a p-type semiconductor layer 65p on the n-type semiconductor layer 62n. The support substrate 61 and the p-type semiconductor layer 65p are electrically connected to each other by a p-type region 64a having a relatively high concentration of impurity.

The semiconductor substrate 60 has a first surface and a second surface opposite from the first surface. The first surface is a surface on the light entry side. Specifically, the first surface is, of a plurality of surfaces that the semiconductor substrate 60 has, a surface on the side where the photoelectric converter 12 is provided. Herein, the “front surface” of the semiconductor substrate 60 corresponds to the first surface, and the “back surface” of the semiconductor substrate 60 corresponds to the second surface. The surface of the semiconductor substrate 60 where the support substrate 61 is provided is the second surface, although the second surface is not shown in FIG. 3.

The support substrate 61 contains an impurity of a first conductivity type. In the present embodiment, the first conductivity type is a p-type. Here, a p-type silicon substrate is shown as an example of the support substrate 61. The p-type impurity contained in the support substrate 61 is, for example, boron.

The support substrate 61 has a connection to a substrate contact provided outside the image capture region R1, although the connection is not shown in FIG. 3. When the imaging device 100 is in operation, the potentials at the support substrate 61 and p-type semiconductor layer 65p are controlled via the substrate contact.

The n-type semiconductor layer 62n contains an impurity of a second conductivity type different from the first conductivity type and is an example of the fourth semiconductor layer located on the opposite side of the p-type semiconductor layer 65p from the photoelectric converter 12. The n-type semiconductor layer 62n is located between the p-type semiconductor layer 65p and the support substrate 61. In the present embodiment, the second conductivity type is an n-type. The n-type impurity contained in the n-type semiconductor layer 62n is, for example, phosphorus.

A well contact (not shown) is connected to the n-type semiconductor layer 62n, although not shown in FIG. 3. The well contact is provided outside the image capture region R1, and via the well contact, the potential at the n-type semiconductor layer 62n is controlled to be constant when the imaging device 100 is in operation. Thus, when the imaging device 100 is in operation, a fixed potential is applied to the n-type semiconductor layer 62n. The provision of the n-type semiconductor layer 62n helps prevent minority carriers from flowing from the support substrate 61 or the peripheral circuits 40 into a charge accumulation region 67n where signal charges are accumulated. In other words, dark current flowing into the charge accumulation region 67n can be reduced by the provision of the n-type semiconductor layer 62n between the support substrate 61 and the p-type semiconductor layer 65p.

The p-type semiconductor layer 65p is an example of the first semiconductor layer containing an impurity of the first conductivity type. The p-type semiconductor layer 65p is provided closer to the front surface of the semiconductor substrate 60 than the n-type semiconductor layer 62n. Specifically, the p-type semiconductor layer 65p is provided on and is in contact with the upper surface of the n-type semiconductor layer 62n.

Each of the n-type semiconductor layer 62n and the p-type semiconductor layer 65p is typically formed by ion implantation of impurity into an epitaxially grown semiconductor film.

The p-type semiconductor layer 65p has a higher impurity concentration than the support substrate 61. The impurity concentration of the support substrate 61 is, for example, approximately 10¹⁵ cm⁻³, and the impurity concentration of the p-type semiconductor layer 65p may be, for example, approximately 10¹⁷ cm⁻³.

As schematically shown in FIG. 3, a plurality of impurity regions are formed inside the p-type semiconductor layer 65p of the semiconductor substrate 60. Specifically, provided in the p-type semiconductor layer 65p are the charge accumulation region 67n, an impurity region 68an, an impurity region 68bn, an impurity region 68cn, an impurity region 68dn, and an impurity region 68en. A blocking structure 69 is also provided in the p-type semiconductor layer 65p. The blocking structure 69 includes a device isolation region 69a and a device isolation region 69b. Details of the blocking structure 69 will be described later.

The charge accumulation region 67n is an impurity region of the second conductivity type inside the p-type semiconductor layer 65p and is an example of the charge accumulation region where the signal charges are accumulated. The n-type charge accumulation region 67n is formed near the front surface of the semiconductor substrate 60, and at least part of the charge accumulation region 67n is located at the front surface of the semiconductor substrate 60. Here, the charge accumulation region 67n includes a first region 67a and a second region 67b being located inside the first region 67a and having a higher impurity concentration than the first region 67a. The impurity concentration of the first region 67a is, for example, approximately 10¹⁷ cm⁻³, and the impurity concentration of the second region 67b is, for example, approximately 3×10¹⁸ cm⁻³. Here, “×” means multiplication.

An insulating layer is disposed on the front surface of the semiconductor substrate 60. In the example shown in FIG. 3, the main surface of the semiconductor substrate 60, which is on the photoelectric converter 12 side, is covered by a first insulating layer 71, a second insulating layer 72, and a third insulating layer 73. The first insulating layer 71 is, for example, a thermally oxidized silicon film. The second insulating layer 72 is, for example, a silicon dioxide layer, and the third insulating layer 73 is, for example, a silicon nitride layer. The second insulating layer 72 may have a stack structure including a plurality of insulating layers, and similarly, the third insulating layer 73 may also have a stack structure including a plurality of insulating layers.

The stack structure of the first insulating layer 71, the second insulating layer 72, and the third insulating layer 73 has a contact hole h1 on the second region 67b of the charge accumulation region 67n. In the example shown in FIG. 3, a contact plug Cp1 which is part of the conductive structure 89 is connected to the second region 67b via the contact hole h1, and thereby, the charge accumulation region 67n is electrically connected to the pixel electrode 12a of the photoelectric converter 12 via the conductive structure 89. In the charge accumulation region 67n, signal charges generated by the photoelectric converter 12 are accumulated.

A junction capacitance formed by a p-n junction between the p-type semiconductor layer 65p as a p-well and the n-type charge accumulation region 67n has a function as a charge accumulation region that temporarily holds signal charges. The conductive structure 89 and the n-type charge accumulation region 67n can be said to form at least part of the above-described charge accumulation node FD.

Note that the formation of the second region 67b in the charge accumulation region 67n is not essential. However, a contact resistance reduction effect can be obtained by connecting the contact plug Cp1 to the second region 67b having a relatively high impurity concentration.

The above-described signal detection circuit 14 is formed at the semiconductor substrate 60. The signal detection circuit 14 in the pixel 10 is electrically separated from the signal detection circuits 14 in the other neighboring pixels 10 because the device isolation region 69a and the device isolation region 69b are disposed between the neighboring pixels 10.

In the signal detection circuit 14, the reset transistor 26 includes the n-type charge accumulation region 67n as one of its drain and source regions and includes the n-type impurity region 68an as the other one of the drain and source regions. The reset transistor 26 further includes a gate electrode 26e on the first insulating layer 71, and a part of the first insulating layer 71 that is located between the gate electrode 26e and the semiconductor substrate 60 functions as a gate insulating film for the reset transistor 26.

The impurity region 68an is formed in the p-type semiconductor layer 65p. A contact plug Cp2 is connected to the impurity region 68an via a contact hole h2. The contact plug Cp2 is electrically connected to the feedback line 53.

The p-type semiconductor layer 65p is further provided with the n-type impurity region 68bn, the impurity region 68cn, the impurity region 68dn, and the impurity region 68en. The impurity region 68bn is an example of the first impurity region. The impurity region 68an, the impurity region 68bn, the impurity region 68cn, the impurity region 68dn, and the impurity region 68en have higher impurity concentrations than the first region 67a of the charge accumulation region 67n.

The signal detection transistor 22 includes the impurity region 68bn, the impurity region 68cn, and a gate electrode 22e on the first insulating layer 71. The impurity region 68bn functions as, for example, the drain region of the signal detection transistor 22, and the impurity region 68cn functions as, for example, the source region of the signal detection transistor 22. In this example, in a layer where the address signal lines 34 and the reset signal lines 36 are located, the gate electrode 22e is connected to a part of the conductive structure 89 where the pixel electrode 12a and the contact plug Cp1 are connected to each other. In other words, the conductive structure 89 also has an electric connection to the gate electrode 22e. The gate electrode 22e is an example of the first gate electrically connected to the photoelectric converter 12.

A contact plug Cp3 is connected the impurity region 68bn via a contact hole h3. The above-described power source wiring 32 as a source-follower power source is electrically connected to the contact plug Cp3. Note that the power source wiring 32 is omitted and not shown in FIG. 3.

The address transistor 24 is formed at the semiconductor substrate 60 as well. The address transistor 24 includes the impurity region 68en, the impurity region 68dn, and a gate electrode 24e on the first insulating layer 71. The n-type impurity region 68en functions as, for example the drain region of the address transistor 24, and the n-type impurity region 68dn functions as, for example, the source region of the address transistor 24. A part of the first insulating layer 71 that is located between the gate electrode 24e and the semiconductor substrate 60 functions as a gate insulating film for the address transistor 24.

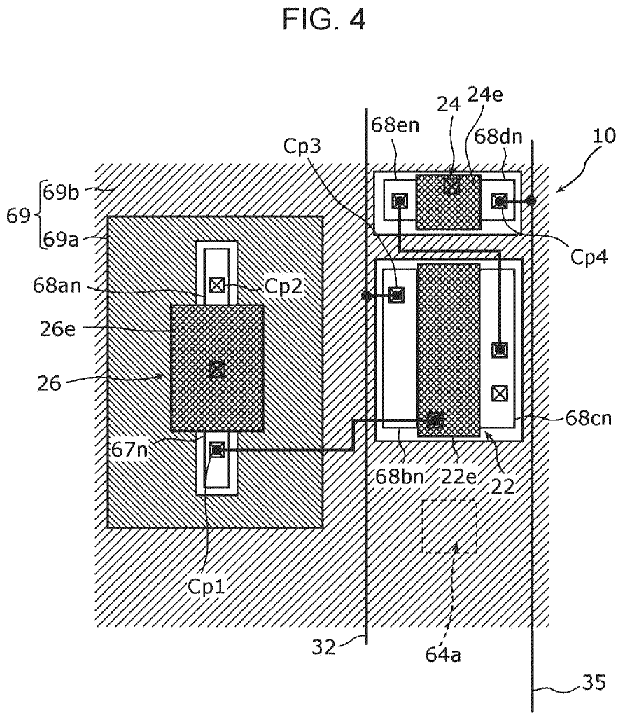

The impurity region 68cn and the impurity region 68en are, as shown in FIG. 4, provided in the semiconductor substrate 60 separately and are electrically connected to each other via wiring, but the present disclosure is not limited to this. The impurity region 68cn and the impurity region 68en may be one diffusion region continuously provided in the semiconductor substrate 60. In other words, the signal detection transistor 22 and the address transistor 24 may share a single diffusion region. The signal detection transistor 22 and the address transistor 24 are thereby electrically connected to each other. As schematically shown in FIG. 3, a contact plug Cp4 is connected to the impurity region 68dn via a contact hole h4. The contact plug Cp4 is electrically connected to the vertical signal lines 35.

Next, the blocking structure 69 is described in detail using FIGS. 3 and 4.

FIG. 4 is a schematic plan view showing an example layout of the elements in the pixel 10 of the imaging device 100 according to the present embodiment. The pixel 10 is, for example, a 3 μm×3 μm square. Although the signal detection transistor 22, the address transistor 24, and the reset transistor 26 in FIG. 3 referred to above are shown appearing in one cross section, this is merely for the sake of convenience of description. Thus, there may be portions such that a section obtained by cutting the element layout shown in FIG. 4 along a certain line does not coincide with the cross section shown in FIG. 3.

As shown in FIGS. 3 and 4, the blocking structure 69 includes the device isolation region 69a and the device isolation region 69b.

The device isolation region 69a is an example of the second impurity region containing an impurity of the first conductivity type. The device isolation region 69b is an example of the third impurity region containing an impurity of the first conductivity type. The device isolation region 69a and the device isolation region 69b are adjacently formed near the front surface of the semiconductor substrate 60. The device isolation region 69a and the device isolation region 69b are adjacent to each other in a plan view, and at least part of each of them is located at the front surface of the semiconductor substrate 60. Note that the device isolation region 69a and the device isolation region 69b do not have to be in contact with each other in a plan view and may be away from each other by a predetermined distance.

As shown in FIG. 4, the blocking structure 69 is located between the charge accumulation region 67n and the signal detection transistor 22. Specifically, in a plan view, at least part of the blocking structure 69 is located between the charge accumulation region 67n and the signal detection transistor 22. The device isolation region 69a is, in a plan view, provided closer to the charge accumulation region 67n than the device isolation region 69b. Specifically, the device isolation region 69a is provided closer to the reset transistor 26 than the device isolation region 69b, the reset transistor 26 including the charge accumulation region 67n as one of its source and drain.

Note that herein, what is meant by “A is located between B and C” is that at least one of line segments each connecting a given point in B and a given point in C passes through A. Also, what is meant by “A is provided closer to C than B” is that the distance between A and C is shorter than the distance between B and C. Thus, in the present embodiment, the distance between the device isolation region 69a and the charge accumulation region 67n is shorter than the distance between the device isolation region 69b and the charge accumulation region 67n. Note that “the distance between A and B” means the shortest distance between A and B, i.e., the distance between a portion of A closest to B and a portion of B closest to A.

As shown in FIG. 4, the device isolation region 69a is disposed around the reset transistor 26. The device isolation region 69b is disposed around each of the signal detection transistor 22 and the address transistor 24. The device isolation region 69a and the device isolation region 69b are adjacent to each other in a plan view, and the transistors are electrically separated from each other. Also, the device isolation region 69a and the device isolation region 69b are disposed approximately 50 nm away from the ends of the source and drain of each of the transistors.

Specifically, in a plan view, the device isolation region 69a is in contact with neither of the charge accumulation region 67n and the impurity region 68an. For example, the device isolation region 69a is formed approximately 50 nm away from each of the charge accumulation region 67n and the impurity region 68an. Note that the gap between the device isolation region 69a and the charge accumulation region 67n and the gap between the device isolation region 69a and the impurity region 68an may be the same as or different from each other.

Also, the device isolation region 69b is in contact with neither of the impurity region 68bn, the impurity region 68cn, the impurity region 68dn, and the impurity region 68en. For example, the device isolation region 69b is formed approximately 50 nm away from each of the impurity region 68bn, the impurity region 68cn, the impurity region 68dn, and the impurity region 68en. Note that the gaps between the device isolation region 69b and each of the impurity region 68bn, the impurity region 68cn, the impurity region 68dn, and the impurity region 68en may be the same as or different from each other.

The device isolation region 69a and the device isolation region 69b have different impurity concentrations from each other. Specifically, the device isolation region 69a has a higher impurity concentration than the device isolation region 69b. Also, the device isolation region 69a and the device isolation region 69b have higher impurity concentrations than the p-type semiconductor layer 65p. For example, the impurity concentration of the device isolation region 69b is two or more times or five or more times as high as that of the p-type semiconductor layer 65p. Also, the impurity concentration of the device isolation region 69a is 1.2 or more times or 1.5 or more times as high as that of the device isolation region 69b. The impurity concentration of the device isolation region 69a is, for example, approximately 1.3×10¹⁸ cm⁻³. The impurity concentration of the device isolation region 69b is, for example, approximately 7×10¹⁷ cm⁻³. Here, “×” means multiplication.

As thus described, in the present embodiment, the device isolation region 69a and the device isolation region 69b having different impurity concentrations are disposed between the charge accumulation region 67n and the impurity region 68bn. Then, the device isolation region 69a disposed closer to the reset transistor 26 including the charge accumulation region 67n as one of its source and drain has a higher impurity concentration than the device isolation region 69b.

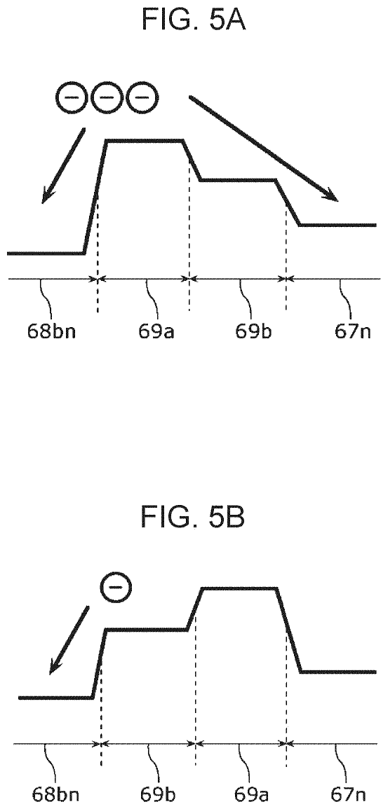

Now, the dark current reduction effect offered by the blocking structure 69 is described from the perspective of potential. FIGS. 5A and 5B are diagrams showing the potential at the blocking structure 69 in the pixel 10 of the imaging devices 100 according to a comparative example and the present embodiment, respectively. Specifically, FIGS. 5A and 5B show the potentials at the charge accumulation region 67n, the impurity region 68bn, and the blocking structure 69 disposed therebetween.

Note that as shown in FIGS. 3 and 4, the blocking structure 69 is in contact with neither of the charge accumulation region 67n and the impurity region 68bn, and a part of the p-type semiconductor layer 65p is present in between. FIGS. 5A and 5B omit and do not show this part of the p-type semiconductor layer 65p. Also, the vicinities of the border between the charge accumulation region 67n and the blocking structure 69 include the part of the p-type semiconductor layer 65p located between the charge accumulation region 67n and the blocking structure 69 as well. Similarly, the vicinities of the border between the impurity region 68bn and the blocking structure 69 include the part of the p-type semiconductor layer 65p located between the impurity region 68bn and the blocking structure 69.

Between FIGS. 5A and 5B, the positional relation between the device isolation region 69a and the device isolation region 69b is different. In the comparative example shown in FIG. 5A, the device isolation region 69b with a low impurity concentration is located closer to the charge accumulation region 67n than the device isolation region 69a with a high impurity concentration. This positional relation is opposite from the embodiment shown in FIG. 5B.

The impurity region 68bn is the drain of the signal detection transistor 22 and receives the power source voltage VDD of approximately 3.3 V. Thus, due to a high electric field, collisional ionization occurs in the vicinities of the border between the impurity region 68bn and the blocking structure 69, generating minority carriers inside the blocking structure 69. A majority of the minority carriers flow to the impurity region 68bn due to the direction of the electric field. However, it has been found that when the power source voltage VDD exceeds 3 V and an increased amount of minority carriers are thereby generated, the minority carriers flow not only to the n-type semiconductor layer 62n disposed on the support substrate 61 side of the p-n junction, but also to the charge accumulation region 67n, thereby increasing dark current.

Now, the reason why the minority carriers flow into the charge accumulation region 67n is described using the potentials at the respective regions. When, for example, the device isolation region 69b closer to the charge accumulation region 67n has a lower impurity concentration than the device isolation region 69a like in the comparative example shown in FIG. 5A, out of the minority carriers generated near the border between the impurity region 68bn and the blocking structure 69, minority carriers that are not absorbed by the impurity region 68bn have, due to the direction of the potential, a potential gradient such that they are likely to flow not only to the impurity region 68bn but also to the charge accumulation region 67n. This also applies to a case where, for example, the device isolation region 69a and the device isolation region 69b have the same impurity concentration.

Meanwhile, when the device isolation region 69a closer to the charge accumulation region 67n has a higher impurity concentration than the device isolation region 69b like in the present embodiment, the device isolation region 69a plays the role as a barrier against diffusion of minority carriers, as shown in FIG. 5B. This makes it difficult for minority carriers to flow to the charge accumulation region 67n and therefore can reduce dark current.

Also, the structure shown in FIG. 5B enables the device isolation region 69b to have a lower impurity concentration, and therefore, the p-n junction electric field at the impurity region 68bn can be reduced to reduce the generation of minority carriers itself. This enables further reduction in minority carriers flowing into the charge accumulation region 67n and therefore can reduce dark current even more.

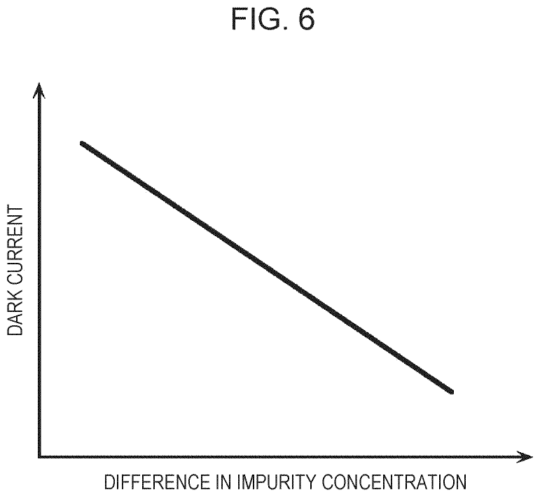

FIG. 6 is a diagram showing how dark current in a pixel of the imaging device according to the present embodiment is dependent on the impurity concentration of the blocking structure 69. In FIG. 6, the horizontal axis represents the difference in the impurity concentration of the device isolation region 69a relative to the device isolation region 69b, and the higher the numerical value, the higher the impurity concentration of the device isolation region 69a.

As shown in FIG. 6, the higher the impurity concentration of the device isolation region 69a is than the device isolation region 69b, the smaller the dark current.

Note that in FIGS. 3 and 4, in a plan view, the device isolation region 69a and the device isolation region 69b are each disposed approximately 50 nm away from the drain and source regions of the transistors. This is to avoid an overlap between a depletion layer of a p-n junction and the device isolation region 69a because if, for example, the drain and source regions are in direct contact with the device isolation region 69a with a high impurity concentration, the electric field intensity at the depletion region of the p-n junction becomes high, increasing the junction leakage.

There are cases where the device isolation region 69b with a low impurity concentration can be closer to the charge accumulation region 67n than the device isolation region 69a with a high impurity concentration, although such a mode is shown in FIG. 5A as a comparative example for the present embodiment. For example, because the device isolation region 69b has a low impurity region, junction leakage due to a p-n junction between the device isolation region 69b and the charge accumulation region 67n is reduced. Thus, when the junction leakage at the charge accumulation region 67n is more dominant than the junction leakage at the impurity region 68bn, dark current may be reduced more when the device isolation region 69b with a low impurity concentration is disposed closer to the charge accumulation region 67n than the device isolation region 69a with a higher impurity concentration.

### Embodiment 2

Next, Embodiment 2 is described.

Embodiment 2 differs from Embodiment 1 in the configuration of the first semiconductor layer. Specifically, in the present embodiment, the first semiconductor layer includes two semiconductor layers having different impurity concentrations. The following description focuses on the differences from Embodiment 1 and omits or simplifies a description of a common point.

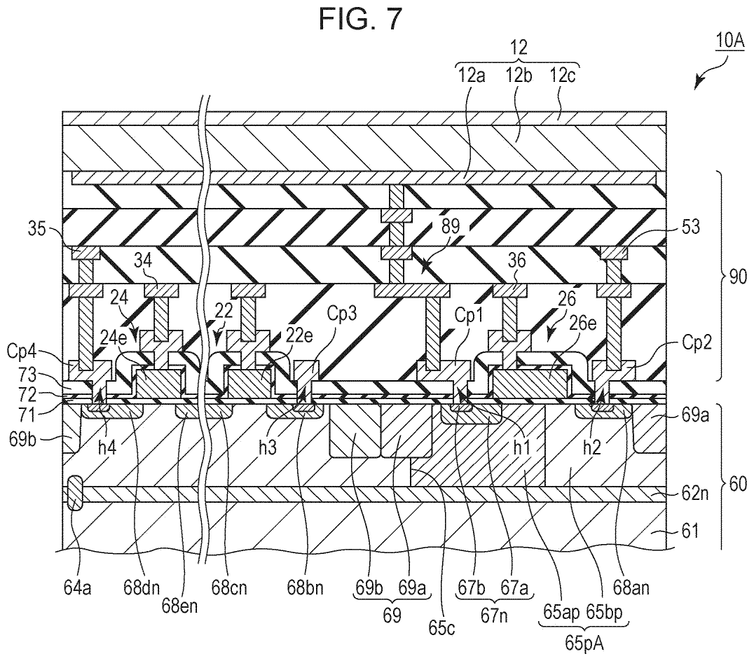

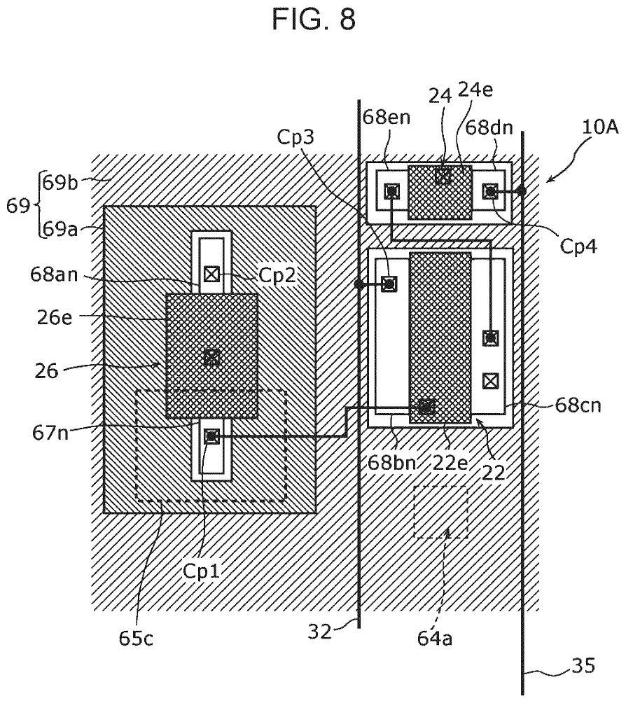

FIG. 7 is a sectional view schematically showing an example of the device structure of a pixel 10A of an imaging device according to the present embodiment. FIG. 8 is a schematic plan view showing an example layout of the elements in the pixel 10A of the imaging device according to the present embodiment.

The main difference between the pixel 10A shown in FIG. 7 and the pixel 10 shown in FIG. 3 is that the pixel 10A is provided with a p-type semiconductor layer 65pA in place of the p-type semiconductor layer 65p. The p-type semiconductor layer 65pA is an example of the first semiconductor layer and includes a p-type semiconductor layer 65ap and a p-type semiconductor layer 65bp.

The p-type semiconductor layer 65bp is an example of the second semiconductor layer containing an impurity of the first conductivity type. The p-type semiconductor layer 65bp is provided around the p-type semiconductor layer 65ap.

The p-type semiconductor layer 65ap is an example of the third semiconductor layer containing an impurity of the first conductivity type. The p-type semiconductor layer 65ap includes the charge accumulation region 67n. The p-type semiconductor layer 65ap is, in a plan view, adjacent to the p-type semiconductor layer 65bp. A border 65c shown in FIGS. 7 and 8 corresponds to a contact portion between the p-type semiconductor layer 65ap and the p-type semiconductor layer 65bp. In a plan view, the border 65c overlaps with the device isolation region 69a. Specifically, the border 65c is in contact with the device isolation region 69a. Thus, the device isolation region 69a is in contact with both of the p-type semiconductor layer 65ap and the p-type semiconductor layer 65bp.

The p-type semiconductor layer 65ap has an impurity concentration different from that of the p-type semiconductor layer 65bp. Specifically, the p-type semiconductor layer 65ap has a lower impurity concentration than the p-type semiconductor layer 65bp. Since the impurity concentration of the region surrounding the charge accumulation region 67n can thus be low, p-n junction leakage at the charge accumulation region 67n can be reduced. The p-type semiconductor layer 65ap has the same impurity concentration as, for example, the support substrate 61. Also, the p-type semiconductor layer 65bp has a lower impurity concentration than the device isolation region 69b. The p-type semiconductor layer 65bp may have the same impurity concentration as the p-type semiconductor layer 65p according to Embodiment 1. The impurity concentration of the p-type semiconductor layer 65ap is, for example, approximately 10¹⁶ cm⁻³. The impurity concentration of the p-type semiconductor layer 65bp is, for example, approximately 10¹⁷ cm⁻³.

The device isolation region 69a of the blocking structure 69 and the charge accumulation region 67n are, in a plan view, provided away from each other by a predetermined distance such as, for example, 50 nm. In the present embodiment, the charge accumulation region 67n is surrounded by the p-type semiconductor layer 65ap with a low impurity concentration and is not in contact with the blocking structure 69 with a high impurity concentration. When the impurity concentration of the p-type semiconductor layer 65ap is thus low, the electric field in the p-n junction between the p-type semiconductor layer 65ap and the charge accumulation region 67n can be mitigated, and thus, p-n junction leakage can be reduced.

Also, although the layers and the regions are shown with their thicknesses emphasized in FIG. 7, the distance between the device isolation region 69a and the n-type semiconductor layer 62n is shorter than the distance between the device isolation region 69a and the charge accumulation region 67n. Thus, minority carriers generated at the electric field in the junction between the impurity region 68bn and the device isolation region 69b are likely to be released to the n-type semiconductor layer 62n via the p-type semiconductor layer 65ap before reaching the charge accumulation region 67n, when seen in a direction horizontal to the semiconductor substrate 60. For this reason, dark current can be reduced even more.

Note that the border 65c may overlap with the device isolation region 69b in a plan view. The border 65c may be located between the impurity region 68bn and the device isolation region 69b in a plan view. Specifically, the border 65c may be not overlapping with the blocking structure 69 in a plan view, and the blocking structure 69 may be surrounded in contact only with the p-type semiconductor layer 65ap.

In these cases as well, dark current can be reduced by the reduction of the p-n junction leakage at the charge accumulation region 67n and by the improvement in the release of minor carriers. Note that when the border 65c overlaps with the impurity region 68bn, p-n junction leakage may vary between pixels. Thus, variation in electric characteristics can be reduced when the border 65c is provided in such a manner as not to overlap with the impurity region 68bn.

### (Modification)

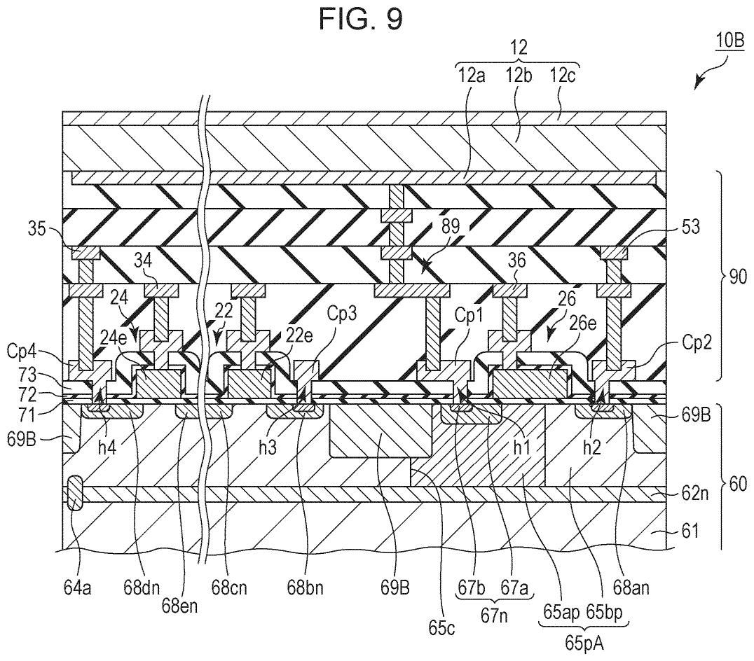

Although the blocking structure 69 in the imaging device according to Embodiment 2 has the device isolation region 69a and the device isolation region 69b having different impurity concentrations from each other, the present disclosure is not limited to this. For example, the device isolation region 69a and the device isolation region 69b may have the same impurity concentration. The following describes, using FIG. 9, the device structure of a pixel in an imaging device according to a modification of the embodiment.

FIG. 9 is a sectional view schematically showing an example of the device structure of a pixel 10B of an imaging device according to the present modification. The main difference between the pixel 10B shown in FIG. 9 and the pixel 10A shown in FIG. 7 is that the pixel 10B includes a blocking structure 69B in place of the blocking structure 69.

The blocking structure 69B is formed of a single impurity region having a substantially uniform impurity concentration. The blocking structure 69B has a higher impurity concentration than both of the p-type semiconductor layer 65ap and the p-type semiconductor layer 65bp. The blocking structure 69B may have the same impurity concentration as the device isolation region 69a or the device isolation region 69b according to Embodiments 1 and 2. Alternatively, the blocking structure 69B may have a higher impurity concentration than the device isolation region 69a and a lower impurity concentration than the device isolation region 69b. For example, the impurity concentration of the blocking structure 69B is greater than or equal to 7×10¹⁷ cm⁻³ and less than or equal to 1.3×10¹⁸ cm⁻³, but the present disclosure is not limited to this.

In a plan view, the blocking structure 69B and the charge accumulation region 67n are provided away from each other by a predetermined distance such as, for example, 50 nm. In the present modification, the charge accumulation region 67n is surrounded by the p-type semiconductor layer 65ap with a low impurity concentration and is not in contact with the blocking structure 69B with a high impurity concentration. When the p-type semiconductor layer 65ap thus has a low impurity concentration, the electric field in the p-n junction between the p-type semiconductor layer 65ap and the charge accumulation region 67n can be mitigated, and the p-n junction leakage can thereby be reduced.

Also, as shown in FIG. 9, the border 65c overlaps with the blocking structure 69B in a plan view. Specifically, the border 65c is in contact with the blocking structure 69B. Thus, the blocking structure 69B is in contact with both of the p-type semiconductor layer 65ap and the p-type semiconductor layer 65bp.

The distance between the blocking structure 69B and the n-type semiconductor layer 62n is shorter than the distance between the blocking structure 69B and the charge accumulation region 67n. Thus, minority carriers generated in the vicinities of the impurity region 68bn are likely to be released to the n-type semiconductor layer 62n via the p-type semiconductor layer 65ap with a low impurity concentration. As a result, minority carriers flowing to the charge accumulation region 67n can be reduced, and dark current can be reduced further compared to a case where the p-type semiconductor layer 65p has a single structure like in Embodiment 1.

Note that the border 65c may be located between the blocking structure 69B and the impurity region 68bn in a plan view, like in Embodiment 2. Specifically, the border 65c may be not overlapping with the blocking structure 69B in a plan view, and the blocking structure 69B may be surrounded in contact only with the p-type semiconductor layer 65ap. In these cases as well, dark current can be reduced by the reduction of the p-n junction leakage at the charge accumulation region 67n and by the improvement in the release of minor carriers.

### Other Embodiments

Although imaging devices according to one or more aspects have thus been described based on the embodiments, the present disclosure is not limited to these embodiments. Modes obtained by applying various modifications conceived of by those skilled in the art to the present embodiments and modes formed by combining constituents in different embodiments are also included in the scope of the present disclosure as long as they do not depart from the gist of the present disclosure.

Also, each of the signal detection transistor 22, the address transistor 24, and the reset transistor 26 described above may be an N-channel MOSFET or a P-channel MOSFET. When each transistor is a P-channel MOSFET, an impurity of the first conductivity type is a p-type impurity, and an impurity of the second conductivity type is an n-type impurity. These transistors do not have to be all N-channel MOSFETs or P-channel MOSFETs. When each transistor in a pixel is an N-channel MOSFET and electrons are used as signal charges, the positions of the source and the drain of each of these transistors may be interchanged.

Also, the embodiments described above may be subject to various kinds of modification, replacement, addition, omission, and the like within the scope of the claims or a scope equivalent thereof.

The present disclosure can be used as an imaging device capable of reducing dark current and, for example, can be applied to, e.g., an image sensor mounted in a camera, a surveillance camera, or a vehicle-mounted camera.

What is claimed is:

1. An imaging device comprising:
a photoelectric converter that generates a signal charge by photoelectric conversion;
a semiconductor substrate that includes a first semiconductor layer containing an impurity of a first conductivity type;
a charge accumulation region that is an impurity region of a second conductivity type in the first semiconductor layer and that accumulates the signal charge;
a transistor that includes, as one of a source and a drain, a first impurity region of the second conductivity type in the first semiconductor layer; and
a blocking structure located between the charge accumulation region and the first impurity region, wherein
the blocking structure includes
a second impurity region of the first conductivity type in the first semiconductor layer and
a third impurity region of the first conductivity type in the first semiconductor layer, the third impurity region having an impurity concentration different from an impurity concentration of the second impurity region, and
on a line connecting the charge accumulation region and the first impurity region, the charge accumulation region, the second impurity region, the third impurity region, and the first impurity region are disposed in this order.

2. The imaging device according to claim 1, wherein
in a plan view, a distance between the second impurity region and the charge accumulation region is shorter than a distance between the third impurity region and the charge accumulation region, and
the second impurity region has a higher impurity concentration than the third impurity region.

3. The imaging device according to claim 1, wherein
the second impurity region is in direct contact with the third impurity region.

4. An imaging device comprising:
a photoelectric converter that generates a signal charge by photoelectric conversion;
a semiconductor substrate that includes a first semiconductor layer containing an impurity of a first conductivity type;
a charge accumulation region that is an impurity region of a second conductivity type in the first semiconductor layer and that accumulates the signal charge;
a transistor that includes, as one of a source and a drain, a first impurity region of the second conductivity type in the first semiconductor layer; and
a blocking structure located between the charge accumulation region and the first impurity region, wherein
the blocking structure includes
a second impurity region of the first conductivity type in the first semiconductor layer and
a third impurity region of the first conductivity type in the first semiconductor layer, the third impurity region having an impurity concentration different from an impurity concentration of the second impurity region,
the first semiconductor layer includes
a second semiconductor layer containing an impurity of the first conductivity type and
a third semiconductor layer being adjacent to the second semiconductor layer in a plan view and having an impurity concentration different from an impurity concentration of the second semiconductor layer,
the charge accumulation region is included in the third semiconductor layer,
the first impurity region is included in the second semiconductor layer, and
in the plan view, the second impurity region overlaps with a border between the second semiconductor layer and the third semiconductor layer.

5. The imaging device according to claim 4, wherein
the semiconductor substrate further includes a fourth semiconductor layer containing an impurity of the second conductivity type, and
the first semiconductor layer is located between the photoelectric converter and the fourth semiconductor layer.

6. The imaging device according to claim 4, wherein
the third semiconductor layer has a lower impurity concentration than the second semiconductor layer.

7. The imaging device according to claim 1, wherein
at least part of the second impurity region, at least part of the third impurity region, or both of the at least part of the second impurity region and the at least part of the third impurity region are located at a surface of the semiconductor substrate.

8. The imaging device according to claim 1, wherein
the transistor includes a first gate electrically connected to the photoelectric converter.

9. The imaging device according to claim 1, wherein
in a plan view, the second impurity region surrounds the charge accumulation region.

10. The imaging device according to claim 1, wherein
in a plan view, the third impurity region surrounds the transistor.

11. The imaging device according to claim 1, wherein
in a plan view, the second impurity region does not overlap with the third impurity region.

12. An imaging device comprising:
a photoelectric converter that generates a signal charge by photoelectric conversion;
a semiconductor substrate that includes a first semiconductor layer containing an impurity of a first conductivity type;
a charge accumulation region that is an impurity region of a second conductivity type in the first semiconductor layer and that accumulates the signal charge;
a transistor that includes, as one of a source and a drain, a first impurity region of the second conductivity type in the first semiconductor layer; and
a blocking structure located between the charge accumulation region and the first impurity region, wherein
the blocking structure includes
a second impurity region of the first conductivity type in the first semiconductor layer and
a third impurity region of the first conductivity type in the first semiconductor layer, the third impurity region having an impurity concentration different from an impurity concentration of the second impurity region,
the second impurity region is in direct contact with the third impurity region, and
in a plan view, the second impurity region does not overlap with the third impurity region.

13. The imaging device according to claim 12, wherein
in the plan view, a distance between the second impurity region and the charge accumulation region is shorter than a distance between the third impurity region and the charge accumulation region, and
the second impurity region has a higher impurity concentration than the third impurity region.
